(19) United States
(12) Patent Application Publication
(10) Pub. No.: US 2026/0344162 A1
(43) Pub. Date: Oct. 29, 2026

(54) LIGHT EMITTING DEVICE AND LIGHTING DEVICE

(71) Applicant: Sanken Electric Co., Ltd., Saitama-ken (JP)

(72) Inventors: Tsutomu Yokota, Saitama-ken (JP); Haruki Takahashi, Saitama-ken (JP)

(73) Assignee: Sanken Electric Co., Ltd., Saitama-ken (JP)

(21) Appl. No.: 19/650,264

(22) Filed: Apr. 16, 2026

(30) Foreign Application Priority Data
Apr. 23, 2025 (JP) 2025-071916

(51) Int. Cl. H10H 29/853; H10H 29/24; H10H 29/854

(52) U.S. Cl. CPC H10H 29/853; H10H 29/24; H10H 29/854

(57) ABSTRACT

A light emitting device is capable of reducing darkening at the corner part side of the light emitting region and suppressing the occurrence of cracks at the corner part of the resin wall, and a lighting device equipped with the same. The light emitting device includes: a light emitting element mounted on a substrate and a resin wall surrounding the light emitting element, wherein in a top view, corner parts are formed on an inner wall constituting an opening of the resin wall, portions of an outer wall paired with the corner parts are expanded outward, and a width of the resin wall at the corner parts is wider than a width of the resin wall between the corner parts.

### CROSS-REFERENCE TO RELATED APPLICATION

This application claims the priority benefit of Japanese application serial no. 2025-071916, filed on Apr. 23, 2025. The entirety of the above-mentioned patent application is hereby incorporated by reference herein and made a part of this specification.

### BACKGROUND

### Technical Field

The disclosure relates to a light emitting device and a lighting device.

### Description of Related Art

Conventionally, a light emitting device has been known in which a light emitting element and reflective resin are disposed in the interior of an opening of a resin wall having an opening formed on a substrate, and a light-transmissive resin including a phosphor layer or light scattering member is disposed to cover these components (Patent Literature 1 (Japanese Patent Application Laid-Open Publication No. 05-029665) and Patent Literature 2(Japanese Patent Application Laid-Open Publication No. 2004-055632)). In top view, a region inside the opening of the resin wall becomes a light emitting region, and by using reflective resin around the light emitting element, improvement in light extraction efficiency is achieved.

In the conventional light emitting device as described above, the inner wall of the resin wall is ring-shaped in a top view, and the light emitting region is often circular. In the case where the light emitting region includes corner parts on the inner wall of the resin wall such as a quadrilateral shape in top view, chamfering is applied to the corner parts of the resin wall to round the corner parts of the light emitting region into an arc shape, for example. As a result, the corner part side of the light emitting region may become dark in top view of the light emitting device.
Additionally, thermal stress may concentrate at the corner parts of the resin wall, causing cracks to occur in the resin wall.

The disclosure provides a light emitting device that can reduce darkening at the corner part side of the light emitting region and suppress occurrence of cracks at the corner parts of the resin wall, and a lighting device equipped with the same.

### SUMMARY

The disclosure provides a light emitting element mounted on a substrate and a resin wall surrounding the light emitting element, wherein corner parts are formed on an inner wall that constitutes an opening of the resin wall in a top view, portions of an outer wall paired with the corner parts are expanded outward, and a width of the resin wall at the corner parts is wider than a width of the resin wall between the corner parts.

According to such a light emitting device, the occurrence of rounded corners with large radii at the corner parts of the inner wall of the resin wall is suppressed, and the darkening at the corner part side of the light emitting region is reduced. Additionally, by increasing the volume of the resin wall at the corner parts, concentration of thermal stress inside the resin wall and occurrence of cracks in the resin wall are suppressed.

At this time, the light emitting device may include a phosphor resin layer provided in the opening of the resin wall above the light emitting element.

According to such a light emitting device, in a light emitting device that emits white light, red light, etc., occurrence of rounded corners with large radii at the corner parts of the inner wall of the resin wall is suppressed, and the darkening at the corner part side of the light emitting region is reduced. Additionally, the concentration of thermal stress and the occurrence of cracks in the resin wall are suppressed.

At this time, the light emitting device may include a reflective resin provided on the substrate between the light emitting element and the resin wall and made of a resin softer than the resin wall.

According to such a light emitting device, the changes in light emission characteristics caused by heat generation of the light emitting element can be suppressed.

At this time, the difference in hardness between the reflective resin layer and the phosphor resin layer based on Shore A hardness (Shore A hardness of phosphor resin layer - Shore A hardness of reflective resin layer) may be 0 or more and 20 or less.

According to such a light emitting device, the peeling at the interface between the reflective resin layer and the light emitting element starting from corner parts or side parts of the light emitting element, or cracking at corner parts of the resin wall can be suppressed.

At this time, the width of the resin wall at the corner part may be wider, in a range of 1/12 to 1/3 times, than a width of the resin wall on a central axis side.

According to such a light emitting device, the generation of rounded corners with large radius at corner parts of the inner wall of the resin wall is suppressed, and the darkening at corner part sides of the light emitting region is reduced. Additionally, the concentration of thermal stress and generation of cracks in the resin wall are suppressed.

At this time, a chamfer radius of the portions of the outer wall of the resin wall paired with the corner parts is larger than a chamfer radius of portions of the inner wall of the resin wall forming the corner, and the chamfer radius of the portions of the corner part of the inner wall of the resin wall may be 200 μm or less.

According to such a light emitting device, the generation of rounded corners with large radius at corner parts of the inner wall of the resin wall is suppressed, and the darkening at corner part sides of the light emitting region is reduced. Additionally, the concentration of thermal stress and generation of cracks in the resin wall are suppressed.

At this time, a lighting device including the above light emitting device may be provided.

According to such a lighting device, the corner parts are easily formed on the inner wall of the resin wall of the light emitting device, and the darkening at corner part sides of the light emitting region is reduced. Additionally, the concentration of thermal stress and generation of cracks in the resin wall are suppressed.

As described above, according to the light emitting device of the disclosure and the lighting device including the same, the darkening at corner part sides of the light emitting region is reduced, and the generation of cracks at the corner parts of the resin wall is suppressed.

### BRIEF DESCRIPTION OF THE DRAWINGS

FIG. 1 is a cross-sectional view showing an example of a light emitting device according to the disclosure.

FIG. 2 is a cross-sectional view passing through a corner part showing an example of a light emitting device according to the disclosure.

FIG. 3 is a plan view showing an example of a light emitting device according to the disclosure.

FIG. 4 is a cross-sectional view showing a modification example of a light emitting device according to the disclosure.

FIG. 5 is a cross-sectional view passing through a corner part showing a modification example of a light emitting device according to the disclosure.

FIG. 6 is a top view showing an example of a lighting device according to the disclosure.

### DESCRIPTION OF THE EMBODIMENTS

Hereinafter, the disclosure will be described in detail, but the disclosure is not limited thereto.

As described above, there has been a demand for a light emitting device capable of reducing the darkening at the corner part side of the light emitting region and suppressing the occurrence of cracks at the corner parts of the resin wall.

As a result of intensive studies, the inventors of the disclosure found the following. With a light emitting device including a light emitting element mounted on a substrate and a resin wall surrounding the light emitting element, wherein corner parts are formed on an inner wall constituting an opening of the resin wall in top view, portions of an outer wall paired with the corner parts are expanded outward, and a width of the resin wall at the corner parts is wider than the resin wall between the corner parts, the darkening at the corner part side of the light emitting region can be reduced and the occurrence of cracks at the corner parts of the resin wall can be suppressed. Based on the findings, the inventors completed the disclosure.

Hereinafter, description is provided with reference to the drawings.

### Light Emitting Device

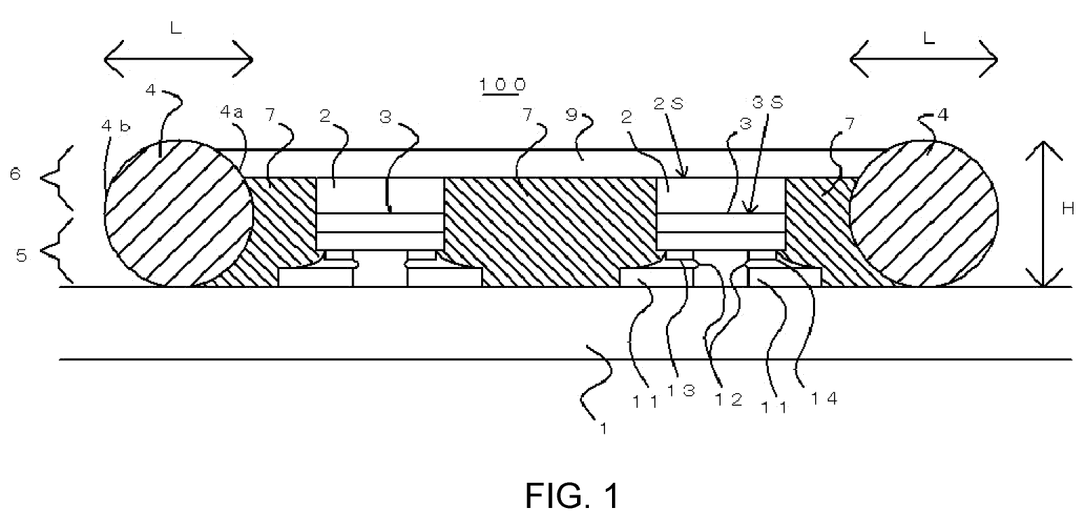

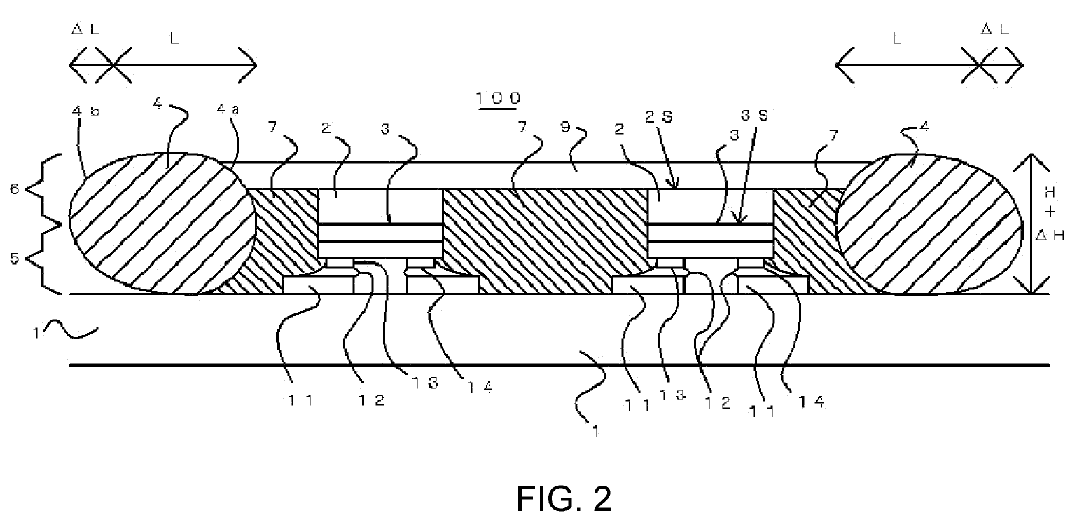

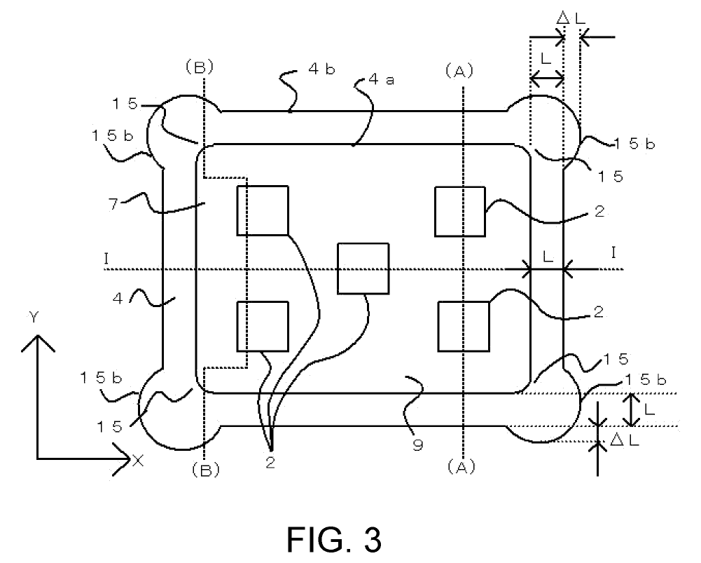

First, the light emitting device according to the disclosure will be described while referring to FIG. 1 (cross-sectional view), FIG. 2 (cross-sectional view), and FIG. 3 (plan view). Here, FIG. 1 shows cross-section A-A in the plan view of FIG. 3, and FIG. 2 shows cross-section B-B passing through corner part 15 of inner wall 4a of resin wall 4 in the plan view of FIG. 3. As shown in FIG. 1, light emitting device 100 according to the disclosure includes light emitting element 2 mounted on substrate 1 and resin wall 4 surrounding light emitting element 2, wherein corner parts 15 are formed on inner wall 4a constituting an opening of resin wall 4 in a top view of FIG. 3, portions of outer wall 4b paired with corner parts 15 are expanded outward, and are wider, by ΔL, than width L of resin wall 4 between corner parts 15. The device may include phosphor resin layer 9 provided in the opening of resin wall 4 above light emitting element 2. The device may include reflective resin 7 provided on substrate 1 between light emitting element 2 and resin wall 4 and composed of a resin softer than resin wall 4. A difference in hardness between reflective resin layer 7 and phosphor resin layer 9 based on Shore A hardness (Shore A hardness of phosphor resin layer - Shore A hardness of reflective resin layer) may be 0 or more and 20 or less. The width L+ΔL of resin wall 4 at corner parts 15 may have a wider width, in a range of 1/8 to 1/4 times width L, on the central axis side of resin wall 4. Resin wall 4 at corner parts 15 may have both inner wall 4a and outer wall 4b having opening reduction part 5 at the bottom and opening expansion part 6 above opening reduction part 5.

### Substrate

In the light emitting device according to the disclosure, the type of substrate 1 is not particularly limited, but it is preferable to use a ceramic substrate as substrate 1. A ceramic substrate has a small linear expansion coefficient among other practical substrates and is close to the temperature properties of resins such as reflective resin 7 provided on substrate 1, so the temperature properties of the entire light emitting device 100 become more stable and better. Note that since a ceramic substrate does not have a resist that reflects light (light-reflective solder resist) applied to its surface, light emitted downward from light emitting element 2 easily transmits to the back side of substrate 1. Therefore, it is preferable to provide reflective resin layer 7 not only on the side surface of light emitting layer 3 of light emitting element 2, but also on the main surface side of substrate 1 below the side surface of light emitting layer 3, to increase the thickness of the resin of reflective resin layer 7 and suppress light leakage to the back side of substrate 1. In this way, light emitting device 100 with good temperature properties while more effectively suppressing light leakage to the back side of substrate 1 may be provided.

Also, in the case of using a flip chip structure light emitting element (LED chip) as described later, it is necessary to provide metal pattern 11 printed on substrate 1. However, since metal pattern 11 absorbs light, if it becomes possible to provide thick reflective resin layer 7 on metal pattern 11, it may be expected that reflective resin layer 7 can reduce light absorption at metal pattern 11.

### Light Emitting Element

In the light emitting device 100 according to the disclosure, the type of light emitting element 2 is not particularly limited. The light emitting element 2 may be selected and used from known LED chips that output light from ultraviolet to blue, or may be an LED chip that outputs red light. LED chips that output light from ultraviolet to blue and LED chips that output red light may be mounted together.

The light emitting element (LED chip) 2 has P-type electrode 13 and N-type electrode 14 provided on one main surface side, and is fixed to metal pattern 11 with bonding layer 12 such as solder paste.

It is desirable to use a flip chip that emits light from the other main surface 2S side of the light emitting element (LED chip) 2. In the light emitting element 2, light is output from a light emitting layer 3; however, the light is output not only from above and below the light emitting element 2, but also from the sides. In a case of using a flip chip, since the base portion of the LED chip (upper surface 2S side of the light emitting element (LED chip) 2) becomes the light extraction surface side, it is relatively easy to secure the distance in the thickness direction from light emitting layer 3 to light extraction surface 2S of the LED chip. As a result, even if the reflective resin 7 is provided up to a height above the side surface of the light emitting layer 3 and up to upper surface 2S of the LED chip 2, the problem of the reflective resin 7 riding up onto the light extraction surface is less likely to occur. Therefore, the light extraction efficiency of the light emitting device 100 can be stably enhanced.

Also, the number of the light emitting elements 2 arranged in the interior of opening of resin wall 4 is not particularly limited. A configuration in which one light emitting element 2 is arranged in one opening may be used, but multiple light emitting elements 2 may be arranged in one opening. For example, as shown in FIG. 3, five light emitting elements 2 are provided at four locations on corner part 15 side of resin wall 4 and at one location near center of the light emitting region.

A buffer film (not shown) that reduces the total reflection of light on the side surface side of the light emitting layer 3 may be provided between the reflective resin layer 7 and the light emitting element 2. Also, apart from reflective resin layer 7, for example a phosphor sheet or protective film, may be provided between the reflective resin layer 7 and the resin wall 4, between the reflective resin layer 7 and the substrate 1, and/or between the reflective resin layer 7 and the phosphor resin layer 9.

### Resin Wall

A resin wall 4 is formed on the substrate 1 so as to surround the light emitting element 2. The light emitting element 2, reflective resin layer 7, phosphor resin layer 9, etc., are arranged in the interior of opening of resin wall 4. The resin wall 4 may also be called a dam or a resin frame. The resin wall 4 can be composed of a resin including a filler that enhances light reflection, such as titanium oxide. The shape, constituent materials, and the like of the resin wall 4 are not particularly limited as long as the light emitting element 2, the reflective resin layer 7, the phosphor resin layer 9, etc., can be arranged in the opening thereof. The region inside inner wall 4a of the resin wall 4, which is the opening of resin wall 4, becomes the light emitting region.

As shown in FIG. 1, an inner wall 4a of the resin wall 4 preferably includes an opening reduction part 5 in which the opening dimension of the opening reduces along a direction normal to the upper surface of the substrate 1 in a cross-sectional view. Also, it is desirable that the reflective resin layer 7 enters into the space between the inner wall 4a of the opening reduction part 5 and the substrate 1. The anchor effect of the opening reduction part 5 can stably suppress the peeling of the reflective resin layer 7, and the reflective resin layer 7 may be stably arranged on substrate 1.

Furthermore, an opening expansion part 6 may be provided on the inner wall 4a above the opening reduction part 5, in which the opening dimension of the opening expands along a direction normal to the upper surface of the substrate 1 in a cross-sectional view. In above case, for example, the cross-sectional shape of the resin wall 4 may be approximately circular, approximately elliptical, approximately rhombic, or a polygonal shape such as approximately hexagonal and approximately octagonal. Here, the description "approximately" includes those with somewhat distorted cross-sectional shapes or partially rounded shapes. Of course, the resin wall 4 may be composed only of the opening expansion part 6 in which the opening dimension of the opening expands along a direction normal to the upper surface of the substrate 1 in a cross-sectional view, or may be a vertical wall with a constant opening dimension. The cross-sectional shape of the resin wall 4 can be adjusted by matching the shape of the nozzle used in extruding resin to form the resin wall 4 to the cross-sectional shape of the resin wall 4 to be formed. By providing the opening expansion part 6 above the opening reduction part 5, the width of the resin wall 4 can be made relatively narrow and the height of the resin wall 4 can be made relatively high. This allows the resin wall 4 to be provided with thick reflective resin layer 7 while relatively suppressing the size of the light emitting device. By making both inner wall 4a and outer wall 4b of resin wall 4 have opening reduction part 5 in the lower portion where the opening dimension reduces along a direction normal to the upper surface of the substrate 1, and the opening expansion part 6 in the upper portion where the opening dimension expands along a direction normal to the upper surface of the substrate 1, and by making the cross-sectional shape of the resin wall 4 as approximately circular, approximately elliptical, approximately rhombic, or a polygonal shape such as approximately hexagonal and approximately octagonal, the resin wall 4 may be provided with a reflective resin layer 7 having relatively high height H while relatively suppressing the size of the light emitting device.

As the resin constituting the resin wall 4, a resin having a Shore A hardness of 53 to 68 may be used. Also, the resin wall 4 is made of a resin harder than the reflective resin layer 7 (the resin of reflective resin layer 7 is softer than the resin of resin wall 4). At this time, it is preferable that the difference in Shore A hardness between the resin of the resin wall 4 and the resin of the reflective resin layer 7 is 25 or more, more preferably 35 or more.

As shown in FIG. 3, when the light emitting device 100 is viewed from above in a plan view, an opening is formed inside the resin wall 4, and the light emitting element 2 is disposed within the opening. Corner parts 15 are formed on inner wall 4a of resin wall 4 that constitutes the opening. In FIG. 3, four corner parts 15 constitute an approximately quadrilateral shape. Corner parts 15 of inner wall 4a of the resin wall 4 may be chamfered with rounded edges. Also, when viewed in a plan view, the opening is shown as four approximately quadrilateral shapes, but may be formed as a square, rectangle, rhombus, or trapezoid. Also, the opening may have a polygonal shape including corner parts 15 other than approximately quadrilateral, such as approximately hexagonal or approximately octagonal. As shown in FIG. 2, inner wall 4a of the resin wall 4 at corner part 15 has an approximately circular arc shape, outer wall 4b of resin wall 4 at corner part 15 has an approximately elliptical shape, and the overall shape is like a flattened circular arc. That is, also at inner wall 4a and outer wall 4b of the resin wall 4 at corner part 15, there is opening reduction part 5 where the opening dimension of the opening reduces along a direction normal to the upper surface of substrate 1 toward the lower side, and opening expansion part 6 where the opening dimension of the opening expands along a direction normal to the upper surface of the substrate 1 is provided above the opening reduction part 5.

As shown in the plan view of FIG. 3, portion 15b of outer wall 4b of resin wall 4 that pairs with corner part 15 is expanded outward, and width L of resin wall 4 at that portion is wide. Outer wall 4b of resin wall 4 has a width of resin wall 4 at portion 15b of outer wall 4b of resin wall 4 that pairs with corner part 15 (width of resin wall 4 at corner part 15) that is wider outward by a maximum of ΔL than width L of resin wall 4 between corner parts 15 (for example, width of resin wall 4 on central axis I side of light emitting device 100 where resin wall 4 is formed linearly when viewed from above in a plan view). Width L of resin wall 4 on central axis I side of light emitting device 100 is, for example, 0.5 mm to 0.8 mm. Also, height H of resin wall 4 on central axis I side of light emitting device 100 is, for example, 0.4 mm to 0.6 mm, and width L of resin wall 4 is larger than height H of resin wall 4. For example, the maximum value of width difference ΔL is in a range of 1/12 to 1/3 times width L of resin wall 4 on central axis I side of light emitting device 100. The volume of resin wall 4 at corner part 15 is larger than the volume of resin wall 4 at portions other than corner parts. Thereby, even in the case where resin wall 4 has a larger linear expansion coefficient than substrate 1, stress applied to corner part 15 of resin wall 4 can be reduced, and occurrence of cracks or the like at corner part 15 of resin wall 4 can be reduced.

For example, by moving a nozzle for extruding resin to form resin wall 4 slightly diagonally outward in the traveling direction near where corner part 15 is scheduled to be formed, or by reducing the moving speed of the nozzle, corner part 15 of inner wall 4a may have small roundness and the location that pairs with corner part 15 of outer wall 4b can be expanded outward, so that corner part 15 of resin wall 4 may have a structure with increased volume.

Here, portion 15b of outer wall 4b of resin wall 4 that pairs with corner part 15 may be chamfered. A chamfer radius of portion 15b of outer wall 4b of resin wall 4 that pairs with corner part 15 is larger than a chamfer radius of portion of inner wall 4a of resin wall 4 at corner part 15. Here, the radius refers to a radius in the case of approximating the wall surface of resin wall 4 including irregularities with an arc, and is not necessarily limited to an arc. The chamfer radius of portion of inner wall 4a of resin wall 4 at corner part 15 is, for example, 200 μm or less. The chamfer radius of portion 15b of outer wall 4b of resin wall 4 that pairs with corner part 15 is, for example, radius of 0.4 mm to 0.75 mm or less. This can widen the distance between light emitting element 2 and corner part 15 of resin wall 4, increase light reflection due to inclination of upper surface of reflective resin 7, and improve luminous flux of semiconductor device 100. Furthermore, reflective resin 7 becomes difficult to ride up onto upper surface of light emitting element 2, improving luminous flux of semiconductor device 100. Also, in FIG. 3, difference ΔL in width of resin wall 4 at all corner parts 15 protrudes in X direction and Y direction, but outer wall 4b of at least one resin wall 4 that pairs with corner part 15 may protrude only in X direction or only in Y direction. Also, maximum value of width ΔL of resin wall 4 protruding at corner part 15 may not be the same for all corner parts 15.

### Reflective Resin Layer

A reflective resin layer 7 is provided in the space inside (opening) surrounded by resin wall 4 on substrate 1, and is also disposed around light emitting element 2. The reflective resin layer 7 according to the disclosure reflects light from light emitting element 2 to efficiently guide light upward and improve light extraction efficiency, and is composed of resin including filler that enhances light reflection such as titanium oxide.

The reflective resin layer 7 according to the disclosure may be composed of resin that is softer than phosphor resin layer 9, that is, resin having smaller Shore A hardness. Softness of resin of reflective resin layer 7 may be, for example, in the range of 17 to 26 in Shore A hardness, more preferably 20. Softness of resin of phosphor resin layer 9 can be, for example, 26 in Shore A hardness.

The reflective resin layer 7 improves light extraction efficiency by covering the side surfaces of light emitting element 2, and by using soft resin, the effects of thermal expansion and contraction caused by heated light emitting element 2 may be absorbed.

In a case where resin of reflective resin layer 7 is significantly harder than resin of phosphor resin layer 9 (Shore A hardness: phosphor resin layer 9 << reflective resin layer 7), as light emitting element 2 becoming high temperature, heat is transmitted to reflective resin layer 7, and reflective resin layer 7 surrounded by resin wall 4 and substrate 1 attempts to expand mainly toward phosphor resin layer 9 side. At this time, when phosphor resin layer 9 having high hardness, internal stress of reflective resin layer 7 increases. As a result, peeling occurs at the interface between reflective resin layer 7 and light emitting element 2 starting from corner parts or side parts of light emitting element 2, or cracks occur at corner part 15 of resin wall 4. Additionally, deterioration of light extraction efficiency of the light emitting device or bias in chromaticity distribution may occur. As the difference in Shore A hardness of resins of reflective resin layer 7 and phosphor resin layer 9 being small, more preferably approximately equivalent, when reflective resin layer 7 attempting to expand toward phosphor resin layer 9 side, phosphor resin layer 9 may deform to follow the deformation of reflective resin layer 7. As a result, it is possible to suppress peeling at the interface between reflective resin layer 7 and light emitting element 2 starting from corner parts or side parts of light emitting element 2, or occurrence of cracks at corner part 15 of resin wall 4. Therefore, it is preferable that the difference in Shore A hardness between resin of reflective resin layer 7 and resin of phosphor resin layer 9 is small, more preferably approximately equivalent. The difference in Shore A hardness between resin of reflective resin layer 7 and resin of phosphor resin layer 9 (Shore A hardness of phosphor resin layer - Shore A hardness of reflective resin layer) is preferably 0 or more and 20 or less, more preferably 0 or more and 18 or less.

As shown in FIG. 1, it is preferable to use light emitting element 2 having a flip chip structure, with reflective resin layer 7 and light emitting element 2 being in contact. Furthermore, by making the thickness of reflective resin layer 7 thicker and reflecting upward while reducing light leakage to the back side of substrate 1, the upward luminance of light emitting device 100 can be further improved. In particular, it is more preferable that the upper surface of reflective resin layer 7 is formed thick to a height higher than the height of upper surface 3S of light emitting layer 3 of light emitting element 2 and up to the height of upper surface 2S of light emitting element 2 or less. This allows light emitted from the side surfaces of light emitting layer 3 to be reflected by the reflective resin. Therefore, the upward luminance of the light emitting device can be further improved.

Additionally, it is desirable that the portion of reflective resin layer 7 on the light emitting element 2 side is provided to a height above the side surfaces of light emitting layer 3 and up to the upper surface of LED chip 2. Furthermore, it is desirable that the portion of reflective resin layer 7 on the resin wall 4 side is provided from at least a partial height on opening reduction part 5 of resin wall 4 to at least a partial height on opening expansion part 6 of resin wall 4. This produces an anchor effect, and while stably suppressing peeling of reflective resin layer 7, reflects light from light emitting element 2 to efficiently guide light upward, and can more effectively suppress light leakage to the back side of substrate 1.

The resin constituting reflective resin layer 7 may be made of silicone resin, hybrid resin having characteristics of both silicone resin and epoxy resin, etc. The base resin of reflective resin layer 7 may be selected from those having different softness (Shore A hardness) using resin of the same type as the resin constituting phosphor resin layer 9.

Additionally, it is also preferable that the resin of reflective resin layer 7 is composed of a material that undergoes curing shrinkage more easily due to heat than the resin of phosphor resin layer 9. The ease of curing shrinkage at this time can be expressed by, for example, the shrinkage rate during curing, and it is preferable that the shrinkage rate of the resin of reflective resin layer 7 is greater than the shrinkage rate of phosphor resin layer 9.

### Phosphor Resin Layer

The resin of phosphor resin layer 9 according to the disclosure satisfies a predetermined softness (Shore A hardness) relationship with the resin of reflective resin layer 7, and is not particularly limited as long as it is composed of resin including phosphor. The softness of the resin of phosphor resin layer 9 can be, for example, Shore A hardness of 15 to 35. The resin constituting phosphor resin layer 9 may be composed of silicone resin, hybrid resin having characteristics of both silicone resin and epoxy resin, and the like.
Additionally, the phosphor may comprise one or multiple types of phosphors such as YAG-based phosphor or CaSN-based phosphor.

Phosphor resin layer 9 is provided above light emitting element 2, and may cover the output surface of the light emitting element. As shown in FIG. 1, it may be formed to cover the entire opening of resin wall 4. Additionally, as shown in FIG. 1, phosphor resin layer 9 may be in contact with the upper portion of opening expansion part 6, or may be provided inside opening expansion part 6.

### Modification Example of Light Emitting Device

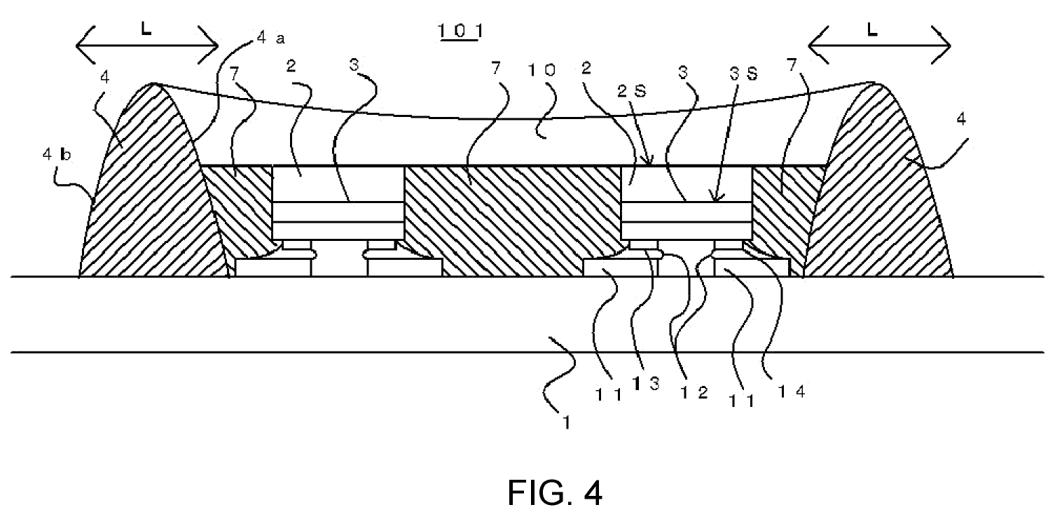

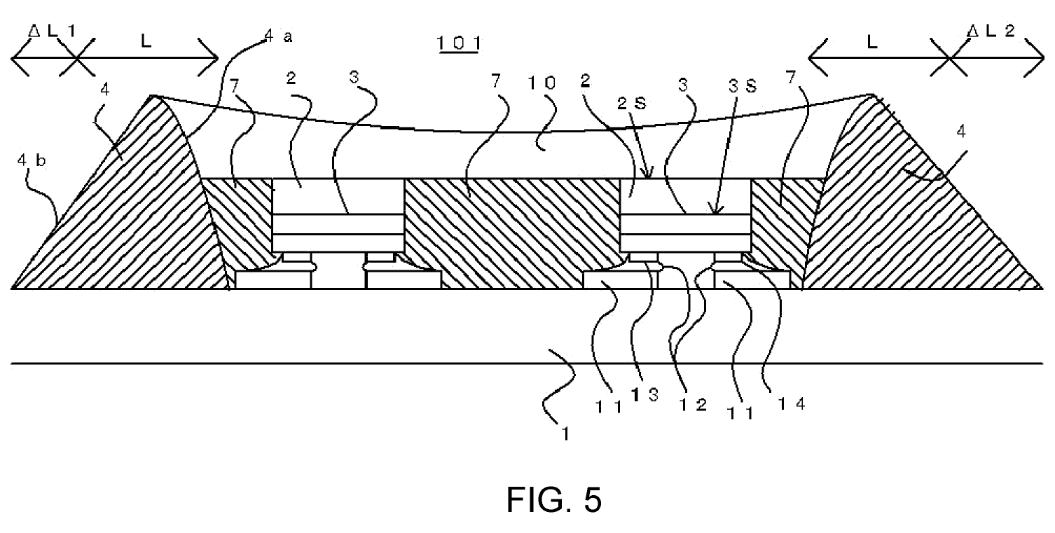

Each of FIGS. 4 and 5 shows a modification example of the light emitting device according to the disclosure, corresponding to the cross-sectional views of FIGS. 1 and 2. The plan view of the modification example of the light emitting device according to the disclosure is, for example, the same as FIG. 3.

Light emitting device 101 of the modification example according to the disclosure includes light-transmissive resin 10 that does not contain phosphor instead of phosphor resin layer 9, and a recess is formed on the upper surface of light-transmissive resin 10, so that the thickness of light-transmissive resin 10 is not constant. Additionally, resin wall 4 is configured only with opening expansion part 6 in which the opening dimension of the opening expands along a direction normal to the upper surface of substrate 1 in a cross-sectional view. In the cross-sectional view passing through resin wall 4 extending linearly in FIG. 4, the inclinations of inner wall 4a and outer wall 4b are approximately equal, but in the cross-sectional view passing through corner part 15 of resin wall 4 in FIG. 5, the inclination of outer wall 4b is gentler than the inclination of inner wall 4a.

Even with such configuration, as shown in FIG. 5, the portion of outer wall 4b of resin wall 4 corresponding to corner part 15 is expanded outward, and the width of resin wall 4 at corner part 15 is widened. Outer wall 4b of resin wall 4 has a width at corner part 15 that is wider outward by a maximum of ΔL than the width L of resin wall 4 between corner parts 15 (for example, the width of resin wall 4 on the central axis side of light emitting device 100 when viewed from above in a plan view). Here, the maximum value L+ΔL1 of the width of resin wall 4 at corner part 15 on the right side of FIG. 5 and the maximum value L+ΔL2 of the width of resin wall 4 at corner part 15 on the left side of FIG. 5 may be different. Light emitting device 101 can also achieve the effects of the disclosure in the same manner as light emitting device 100.

### Lighting Device

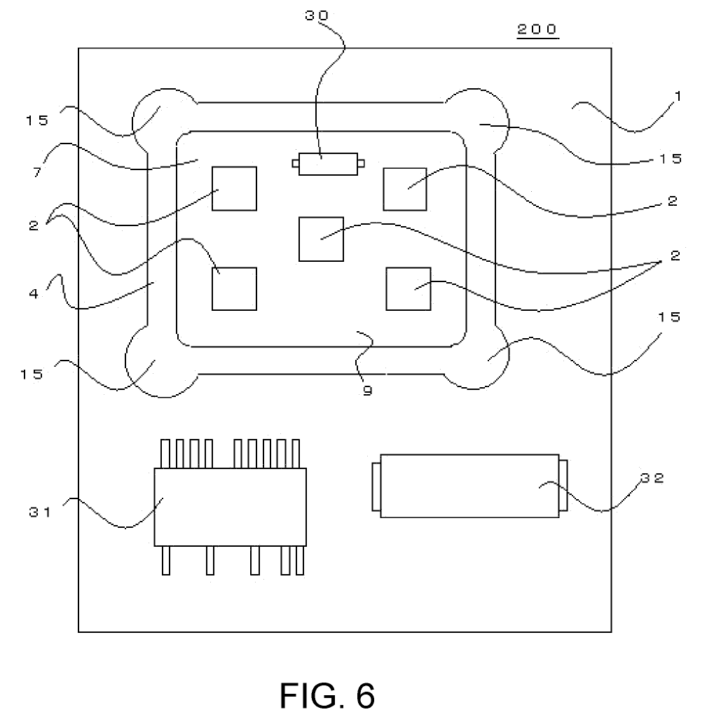

The disclosure may provide lighting device 200 including the above-described light emitting device 100. FIG. 6 shows an example of lighting device 200 (top view). Note that phosphor resin layer 9 is not illustrated so that components such as light emitting elements can be seen. Lighting device 200 may be provided that includes a light emitting device having light emitting element 2 and Zener diode 30, etc., within the opening of resin wall 4 provided on substrate 1, and diode 31 and IC 32 on substrate 1 outside the opening of resin wall 4. The specific application of the lighting device is not particularly limited, and may be indoor lighting, outdoor lighting, headlamps for automobiles, etc.

As described above, the light emitting device of the disclosure is a light emitting device that can reduce darkening at the corner part side of the light emitting region and suppress the occurrence of cracks at the corner part of the resin wall.

This specification includes the following aspects.
1: A light emitting device comprising: a light emitting element mounted on a substrate and a resin wall surrounding the light emitting element, wherein in a top view, corner parts are formed on an inner wall constituting an opening of the resin wall, portions of an outer wall paired with the corner parts are expanded outward and a width of the resin wall at the corner parts is wider than a width of the resin wall between the corner parts.
2: The light emitting device of 1 above, comprising a phosphor resin layer provided in the opening of the resin wall above the light emitting element.
3: The light emitting device of 1 above, comprising a reflective resin provided on the substrate between the light emitting element and the resin wall and wherein the reflective resin is made of a resin softer than the resin wall.
4: The light emitting device of 1, 2 or 3 above, wherein a difference in hardness between the reflective resin layer and the phosphor resin layer based on Shore A hardness (Shore A hardness of phosphor resin layer - Shore A hardness of reflective resin layer) is 0 or more and 20 or less.
5: The light emitting device of 1,2, 3 or 4 above, wherein the width of the resin wall at the corner parts is wider, in a range of 1/12 to 1/3 times, than a width on a central axis side of the resin wall.
6: The light emitting device of 1, 2, 3, 4 or 5 above, wherein a chamfer radius of the portions of the outer wall of the resin wall paired with the corner parts is larger than a chamfer radius of portions of the inner wall of the resin wall forming the corner parts, and the chamfer radius of the portions of the corner part of the inner wall of the resin wall is 200 μm or less.
7: A lighting device including the light emitting device of 1, 2, 3, 4, 5, or 6 above.

Note that the disclosure is not limited to the above embodiment. The above embodiment is an example, and anything having substantially the same configuration as the technical idea described in the claims of the disclosure and exhibiting similar effects is included in the technical scope of the disclosure.

What is claimed is:

1. A light emitting device comprising:
a light emitting element mounted on a substrate; and
a resin wall surrounding the light emitting element,
wherein in a top view, corner parts are formed on an inner wall constituting an opening of the resin wall, portions of an outer wall paired with the corner parts are expanded outward, and
a width of the resin wall at the corner parts is wider than a width of the resin wall between the corner parts.

2. The light emitting device according to claim 1, comprising a phosphor resin layer provided in the opening of the resin wall above the light emitting element.

3. The light emitting device according to claim 2, comprising a reflective resin provided on the substrate between the light emitting element and the resin wall and wherein the reflective resin is made of a resin softer than the resin wall.

4. The light emitting device according to claim 3, wherein a difference in hardness between the reflective resin layer and the phosphor resin layer based on Shore A hardness (Shore A hardness of phosphor resin layer - Shore A hardness of reflective resin layer) is 0 or more and 20 or less.

5. The light emitting device according to claim 1, wherein the width of the resin wall at the corner parts is wider, in a range of 1/12 to 1/3 times, than a width of the resin wall on a central axis side.

6. The light emitting device according to claim 1, wherein a chamfer radius of the portions of the outer wall of the resin wall paired with the corner parts is larger than a chamfer radius of portions of the inner wall of the resin wall forming the corner parts, and
the chamfer radius of the portions of the corner part of the inner wall of the resin wall is 200 μm or less.

7. A lighting device comprising the light emitting device according to claim 1.
